(19) United States
(12) Patent Application Publication
(10) Pub. No.: US 2025/0226279 A1
(43) Pub. Date: Jul. 10, 2025

(54) AREA EFFECTIVE HEAT SINK

(71) Applicant: Murata Manufacturing Co., Ltd., Kyoto (JP)

(72) Inventors: Saloni Chaurasia, Leandar, TX (US); Shishir Ray, San Diego, CA (US); Jagar Singh, Clifton Park, NY (US)

(21) Appl. No.: 18/404,866

(22) Filed: Jan. 4, 2024

(51) Int. Cl. H01L 23/367; H01L 21/8238; H01L 27/06; H01L 27/092; H01L 29/66

(52) U.S. Cl. CPC H01L 23/367; H10D 64/017; H10D 84/0172; H10D 84/0188; H10D 84/038; H10D 84/856; H10D 88/00

(57) ABSTRACT

An integrated circuit includes a substrate, a metal layer positioned above the substrate, an oxide layer disposed between the substrate and the metal layer, and a transistor disposed on the substrate between the substrate and the oxide layer. The transistor includes a source, a gate, and a drain. A dummy contact is positioned within the oxide layer above and in thermal contact with the gate of transistor. The dummy contact is electrically isolated and configured to convey heat generated by the transistor during operation of the integrated circuit to the metal layer.

### TECHNICAL FIELD

The present disclosure relates to heat sinks usable in integrated circuits and other electrical devices, devices including such heat sinks, and methods of making and using the same. More particularly, the disclosure relates to heat sinks including one or more dummy contacts positioned proximate a transistor of an integrated circuit.

### BACKGROUND

Three-dimensional integrated circuits (3DICs) include a plurality of stacked wafers or chips each including various electrical components, such as transistors. Transistors (e.g., field effect transistors (FETs)) can suffer from self-heating during operation of the 3DIC that can degrade performance. This is especially of concern in high voltage IO devices and the self-heating may be exacerbated due to the configuration of the 3DIC. As devices continue to shrink in size, there remains a need for area effective heat dissipation solutions.

### BRIEF SUMMARY

According to embodiments of the present disclosure, an integrated circuit includes a substrate, a metal layer positioned above the substrate, an oxide layer disposed between the substrate and the metal layer. A transistor is disposed on the substrate between the substrate and the oxide layer, and the transistor includes a source, a gate, and a drain. A dummy contact is positioned within the oxide layer above and in thermal contact with the gate of transistor. The dummy contact is electrically isolated and configured to convey heat generated by the transistor during operation of the integrated circuit to the metal layer.

According to embodiments of the present disclosure, a three-dimensional integrated circuit includes a first complementary metal-oxide semiconductor (CMOS) wafer and a second CMOS wafer disposed on and electrically connected to the first CMOS wafer. The second CMOS wafer includes a field effect transistor structure having a gate, a plurality of aligned pairs of sources and drains, the sources being disposed on one side of the gate and drains being disposed on an opposite side of the gate, an oxide layer disposed on the field effect transistor structure, a metal layer disposed on the oxide layer such that the oxide layer is between the metal layer and the field effect transistor structure, a plurality of thermally conductive contacts disposed within the oxide layer. The thermally conductive contacts are each electrically isolated and in thermal contact with the field effect transistor structure.

### BRIEF DESCRIPTION OF THE DRAWINGS

Various embodiments of the present disclosure will be understood more fully from the detailed description given below and from the accompanying drawings. In the drawings, like reference numbers may indicate identical or functionally similar elements. Embodiments are described in detail hereinafter with reference to the accompanying figures, in which:

FIG. 1 is a diagrammatic cross-section of a 3DIC according to an embodiment of the present disclosure.

FIG. 2 is a partial diagrammatic cross-section of an FET within a 3DIC according to an embodiment of the present disclosure.

FIG. 3 is a partial diagrammatic cross-section of an FET within a 3DIC according to an embodiment of the present disclosure.

FIG. 4 is a partial diagrammatic cross-section of an FET within a 3DIC according to an embodiment of the present disclosure.

FIG. 5 is a diagrammatic top view of an FET within a 3DIC according to an embodiment of the present disclosure.

FIG. 6 is a diagrammatic top view of an FET within a 3DIC according to an embodiment of the present disclosure.

FIG. 7 is a diagrammatic top view of an FET within a 3DIC according to an embodiment of the present disclosure.

FIG. 8 is a diagrammatic top view of an FET within a 3DIC according to an embodiment of the present disclosure.

FIG. 9 is a diagrammatic top view of an FET within a 3DIC according to an embodiment of the present disclosure.

FIG. 10 is a diagrammatic top view of an FET within a 3DIC according to an embodiment of the present disclosure.

FIG. 11 is a diagrammatic top view of an FET within a 3DIC according to an embodiment of the present disclosure.

FIG. 12 is a flow chart depicting a method according to an embodiment of the present disclosure.

### DETAILED DESCRIPTION

Although the claimed subject matter will be described in terms of certain embodiments and examples, other embodiments and examples, including embodiments and examples that do not provide all of the benefits and features set forth herein, are also within the scope of this disclosure. Various structural, logical, and process step changes may be made without departing from the scope of the disclosure.

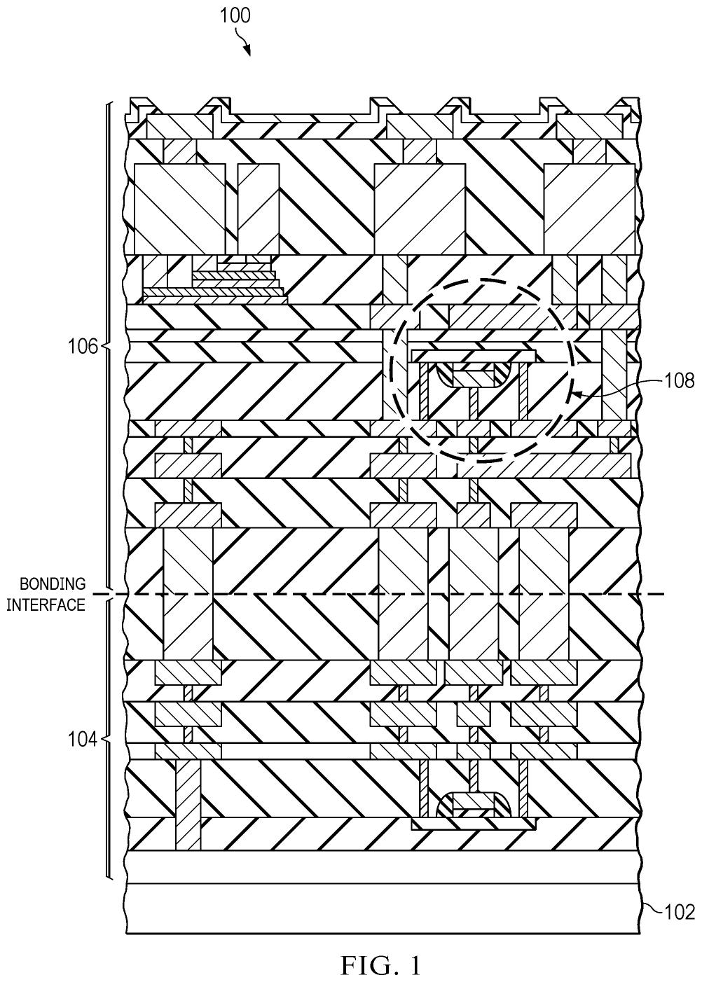

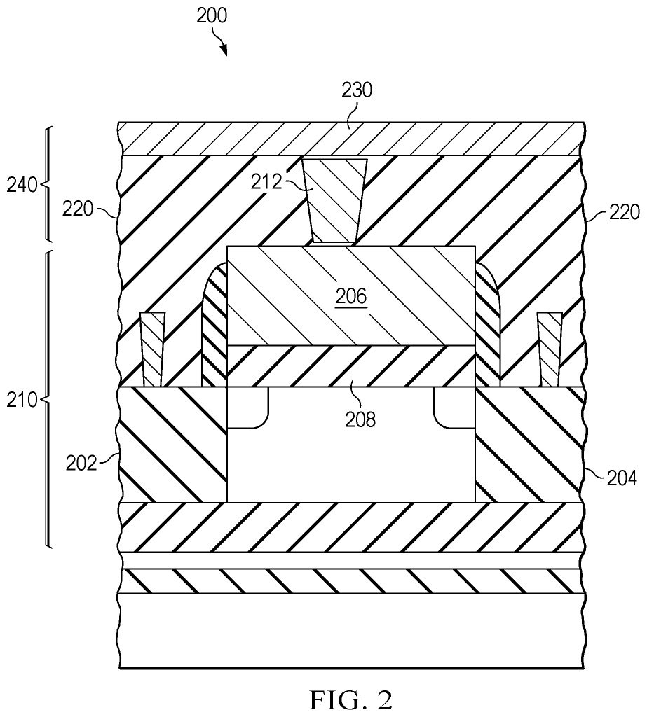

With reference to FIG. 1, a 3DIC 100 includes a first wafer 104 disposed on a substrate 102, such as silicon, and a second wafer 106 disposed on the first wafer 104. Each of the first wafer and the second wafer may include a combination of implants and/or layers to form active and/or passive electronic components and/or mechanical structures. For example, in FIG. 1, an FET 108 is shown within the second wafer 106. According to one or more embodiments, the FET 108 may include a metal-oxide-semiconductor (MOS) FET or a complementary metal-oxide-semiconductor (CMOS) FET. Because the second wafer 106 does not include a backside handle wafer (such as substrate 102 for the first wafer 104), heat produced by the FET 108 during operation of the 3DIC 100 cannot easily dissipate. That is, most of the heat is generated into active areas. At high voltages (e.g., greater than 1.8V), the heat generated by the FET 108 can lead to current degradation of as much as 7 to 8%. Embodiments of the present disclosure provide heat sink structures, as described in more detail below with respect to FIGS. 2-11, that alleviate FET self-heating. Further, the heat sinks described herein occupy much less area as compared to traditional heat sinks. The heat sinks described herein may also act to dissipate heat from the FET or other components of a 3DIC during fabrication thereof, thereby protecting such components from damage.

Turning to FIG. 2, an FET structure 200 includes an FET 210 embedded in an electrically insulating oxide layer 220. The oxide layer 220 electrically isolates the FET 210 from conductive metal layer 230. The FET 210 comprises a source 202, a drain 204, and a gate 206 atop an insulating gate oxide (GOX) layer 208.

A dummy contact 212 is positioned in close proximity to and is in thermal contact with the gate 206. The dummy contact 212 is electrically isolated from the FET 210. As used herein, “dummy contact” and “thermally conductive contact” may be used interchangeable to refer to an electrically isolated and thermally conductive material. As used herein, the adjective “dummy” refers to an electrical isolation.

The composition, shape, and size of the dummy contact 212 is not particularly limited. In some embodiments, the dummy contacts 212 may be formed of tungsten, copper, titanium, aluminum, silicides, germanium, carbon nanotubes (CNT), or combinations thereof. In any embodiments, the dummy contacts 212 may have a greater thermal conductivity than the material forming the oxide layer 220. As used herein, “thermally conductive” refers to having a thermal conductivity greater than an oxide layer material within an integrated circuit, such as silica. In some embodiments, thermally conductive materials referenced herein may have a thermal conductivity at least 2×, at least 5×, or at least 10× that of the oxide layer material.

In operation, the dummy contact 212 conveys heat generated by the FET 210 to a metal layer 230. As shown in FIG. 2, the dummy contact 212 may be in thermal contact with both the gate 206 and the metal layer 230. Together, the dummy contact 212 and the metal layer 230 constitute a heat sink 240.

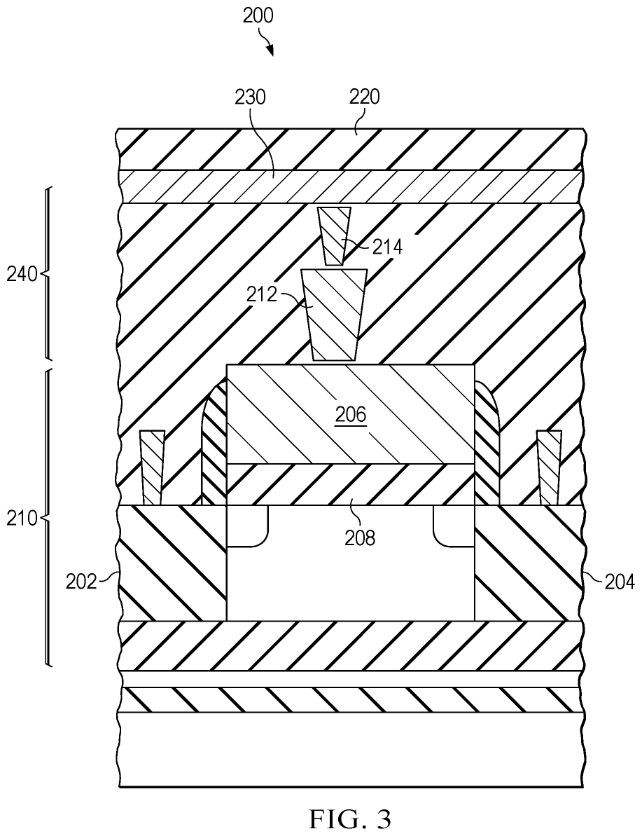

In some embodiments, such as that shown in FIG. 3, the dummy contact 212 may be in thermal contact with the gate 206 and a dummy via 214. The dummy via 214 is thermally conductive and electrically isolated and is in thermal contact with the dummy contact 212 and the metal layer 230, such that the dummy contact 212, the dummy via 214, and the metal layer 230 constitute the heat sink 240.

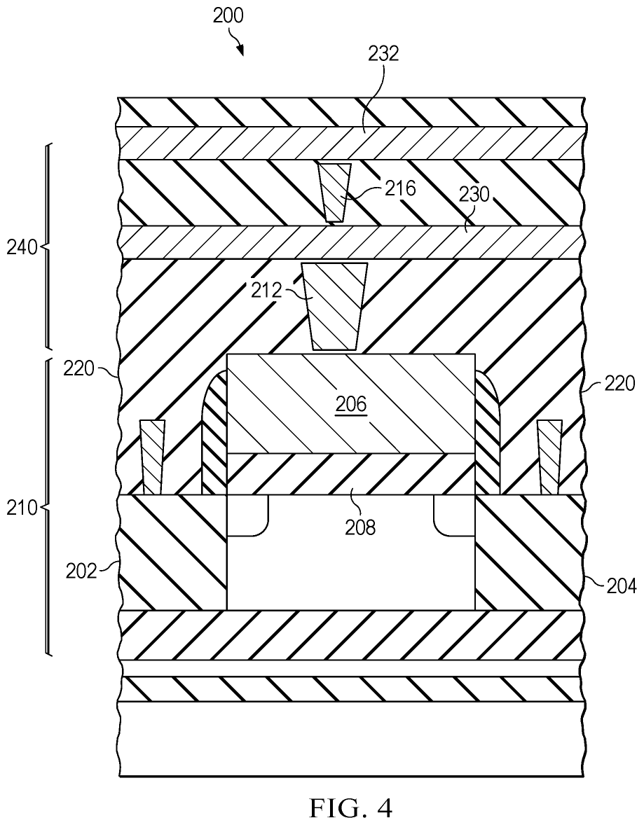

As shown in FIG. 4, the heat sink 240 may include additional metal layers, such as metal layer 232 and dummy vias, such as dummy via 216, between the metal layers to convey the heat from the FET 210 to a desired location, such as an upper most metal layer. In some embodiments, the heat sink 240 may include at least one dummy contact and at least one metal layer. In some embodiments, the heat sink 240 includes at least one dummy contact, at least two metal layers, and at least one dummy via between each pair of successive metal layers.

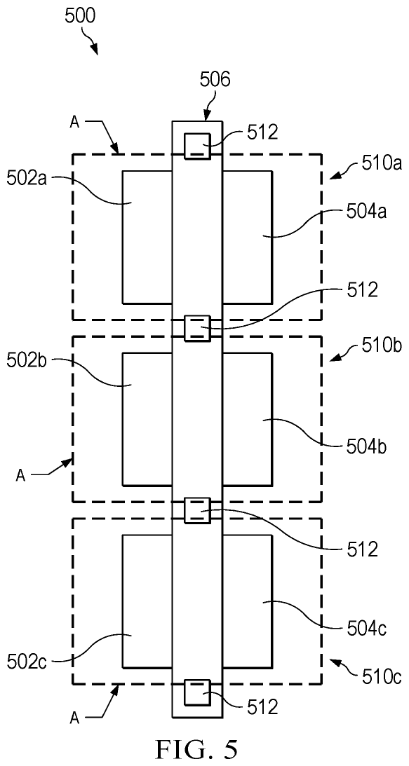

Turning to FIG. 5, a top view of an FET structure 500 is shown having a series of FETs 510a, 510b, and 510c each respectively including sources 502a, 502b, 502c and drains 504a, 504b, 504c, and a gate 506 disposed between the sources 502a, 502b, 502c and drains 504a, 504b, 504c. Although the gate 506 is depicted as being continuous between FETs 510a, 510b, and 510c, the FETs 510a, 510b, and 510c may be independent from one another, each having its own gate. The boxed areas A show an active area of the FET structure 500. The active area A extends the width of any given pair of sources and drains (i.e., 502a and 504a, 502b and 504b, or 502c and 504c). Gaps between the pairs of sources and drains may be referred to an inactive area.

As shown in FIG. 5, dummy contacts 512 are positioned above the gate 506 outside of the active areas A. Positioning the dummy contacts 512 in this manner may help to reduce interference with capacitance of the FET structure 500 in applications where this is needed.

Each of the dummy contacts 512 may be as described above. The dummy contacts 512 are electrically isolated from and in thermal contact with the gate 506 and are further in direct or indirect thermal contact with additional thermally conductive structures above the dummy contacts 512. For example, as described above with reference to FIG. 2-4, the dummy contacts 512 may be in thermal contact with a via or a metal layer or a series of vias and metal layers to convey heat away from the FET structure 500.

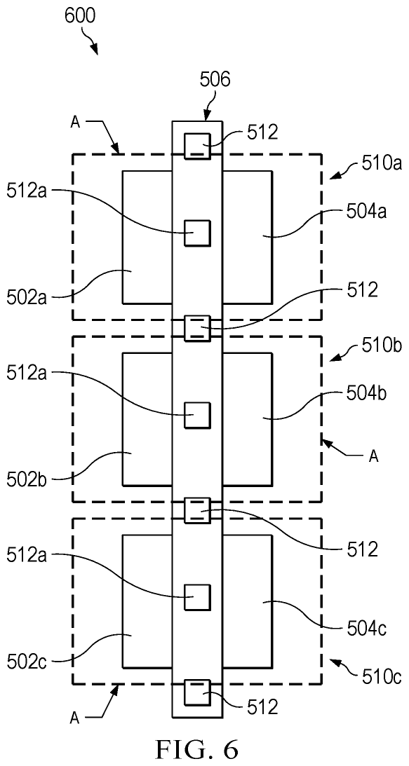

In some embodiments, as shown in FIG. 6, the FET structure 600 includes dummy contacts 512a also be positioned over the active areas A. The dummy contacts 512a may be as described above with respect to the dummy contacts 512. In some embodiments, dummy contacts 512, 51a may be positioned only within the active areas, only outside the active areas, both inside and outside of the active areas, or outside of the active areas and within some but not all of the active areas. In some embodiments, the dummy contacts 512a may differ from the dummy contacts 512 in shape, size, or composition. For example, in some embodiments, the dummy contacts 512a may have a higher or lower thermal conductivity than the dummy contacts 512. In some embodiments, the dummy contacts 512a may have a larger or smaller volume that the dummy contacts 512. In some embodiments, the dummy contacts 512a may have a smaller or larger cross-sectional area than the dummy contacts 512 taken in a longitudinal direction of the 3DIC.

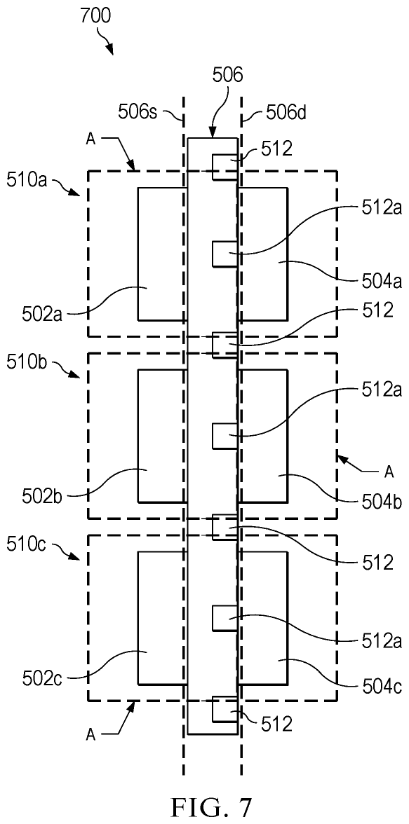

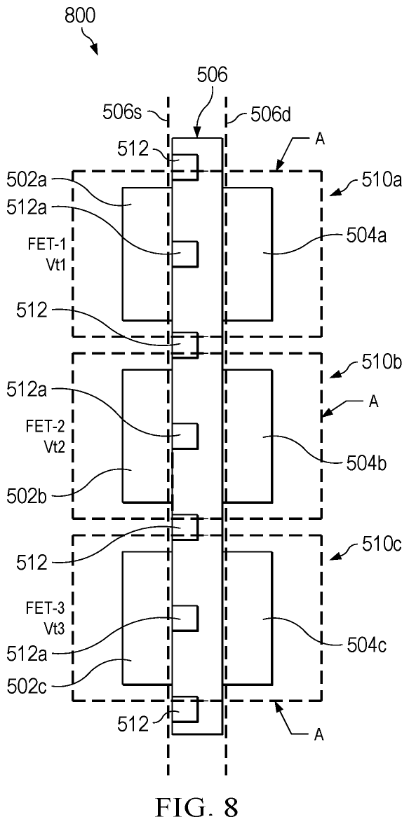

Turning to FIG. 7, the FET structure 700 is shown with a source edge 506s of the gate 506 running between the sources 502a, 502b, 502c and the gate 506 and a drain edge 506d of the gate 506 running between the drains 504a, 504b, 504c and the gate 506. In the FET structure 700, the dummy contacts 512, 512a are all positioned closer to the drain edge 506d than the source edge 506s. Since a majority of heat produced by the FET structure 700 may occur near the drain edge 506d, this configuration may more effectively dissipate the heat. However, other configurations are disclosed herein. For example, the FET structure 800 in FIG. 8 provides all of the dummy contacts 512, 512a closer to the source edge 506s than the drain edge 506d.

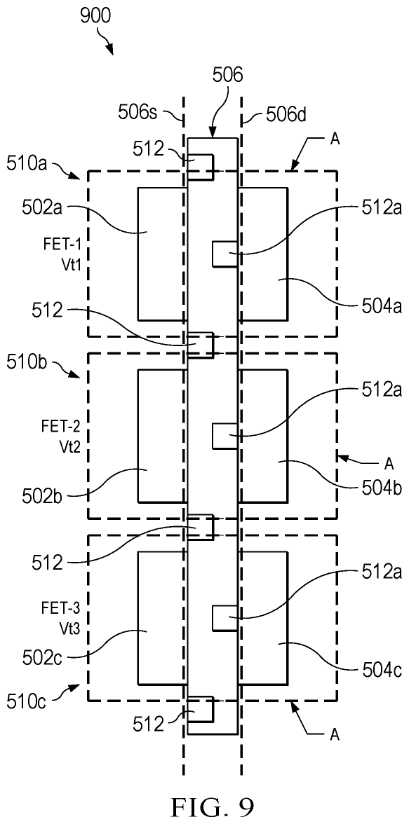

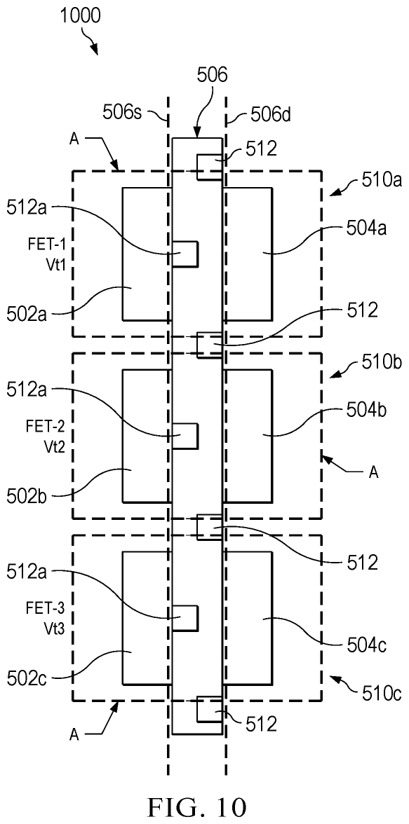

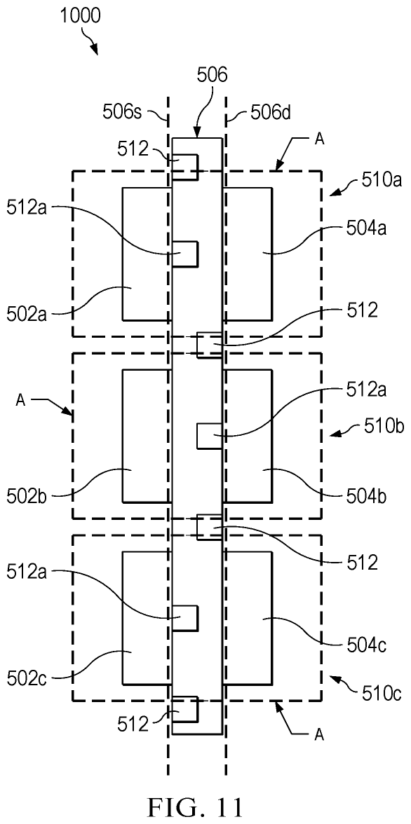

In the FET structure 900 of FIG. 9, the dummy contacts 512 are positioned closer to the source edge 506s than the drain edge 506d and the dummy contacts 512a are positioned closer to the drain edge 506d than the source edge 506s. Conversely, in the FET structure 1000 of FIG. 10, the dummy contacts 512 are positioned closer to the drain edge 506d than the source edge 506s and the dummy contacts 512a are positioned closer to the source edge 506s than the drain edge 506d. In the FET structure 1100 of FIG. 11, some of the dummy contacts 512 are positioned closer to the drain edge 506d than the source edge 506s, some of the dummy contacts 512 are positioned closer to the source edge 506s than the drain edge 506d, some of the dummy contacts 512s are positioned closer to the drain edge 506d than the source edge 506s, and some of the dummy contacts 512s are positioned closer to the source edge 506s than the drain edge 506d. The embodiments shown in FIGS. 9-11 may be well suited for FETs utilizing bidirectional flow, wherein the sources and drains are interchanged based on the direction of flow and hot spots may likewise migrate.

Although specific embodiments have been shown in the figures and discussed above, combinations of the foregoing features are also included in the present disclosure. For example, the variation in positioning within or outside of active areas as well as the variation in size, shape, or composition discussed with reference to FIGS. 5 and 6 may be combined with the variation in positioning relative to the source edge 506s and the drain edge 506d discussed with reference to FIGS. 7-11. Additionally, any of the foregoing features may be further combined with the heat sink 240 structures discussed with reference to FIGS. 2-4.

In any embodiments, the dummy contacts and/or the heat sink structure may be incorporated into any semiconductor wafer or chip, such as the 3DIC described above. The semiconductor wafers or chips may be incorporated into an electronic device, such as a mobile phone

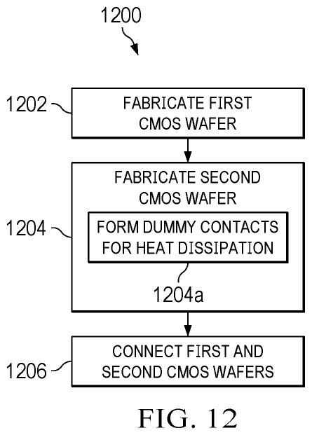

Turning to FIG. 12, a method 1200 is shown. The method 1200 includes a step 1202 of fabricating a first CMOS wafer (or chip). This may be done using known techniques, such as silicon on insulator (SOI) technology. Step 1204 includes fabricating a second CMOS wafer (or chip) having one or more FETs and further includes step 1204a of forming dummy contacts as described above proximate the FETs to provide heat dissipation. Step 1204a may also include forming dummy vias stacked above the dummy contacts to a desired position within the second CMOS wafer (e.g., an upper most metal layer). The method 1200 further includes a step 1206 of electrically connecting the first CMOS wafer and the second CMOS wafer to form a 3DIC. The 3DIC may include two or more stacked chips or wafers, wherein at least one includes the dummy contacts described herein. Step 1206 may be achieved using known techniques, such as chip-on-wafer or wafer-on-wafer technologies. The method 1200 may include additional steps, such as incorporating the 3DIC into an electronic device, operating the electronic device, and/or dissipating heat generated by an FET within the 3DIC via the dummy contacts.

An integrated circuit has been described herein. The integrated circuit includes a substrate, a metal layer positioned above the substrate, an oxide layer disposed between the substrate and the metal layer, a transistor disposed on the substrate between the substrate and the oxide layer, the transistor comprising a source, a gate, and a drain and a dummy contact positioned within the oxide layer above and in thermal contact with the gate of transistor. The dummy contact is electrically isolated and configured to convey heat generated by the transistor during operation of the integrated circuit to the metal layer. The integrated circuit may include any of the following features or combinations thereof:
a thermally conductive via formed between the dummy contact and the metal layer;
a second oxide layer disposed on the metal layer; a second metal layer disposed on the second oxide layer; and a thermally conductive via formed through the second oxide layer between the metal layer and the second metal layer, the thermally conductive via configured to convey the heat generated by the transistor to the second metal layer;
wherein the integrated circuit is a three dimensional integrate circuit comprising a plurality of stacked integrated circuits on a handle wafer, the handle wafer forming a bottom surface of the integrated circuit;
wherein the transistor is disposed within a top integrated circuit of the plurality of stacked integrated circuits; and wherein the top integrated circuit further comprises one or more stacked thermally conductive vias configured to convey the heat generated by the transistor to a top metal layer of the top integrated circuit;
wherein the gate extends beyond the source and drain, and an active area of the gate is defined as an area of the gate directly between the source and the drain; and wherein the dummy contact is positioned outside of the active area;
a second dummy contact positioned within the oxide layer above the active area of the gate and in thermal contact with the gate, wherein the second dummy contact is electrically isolated and configured to convey heat generated by the transistor to the metal layer;
wherein a distance between the dummy contact and the drain is less than a distance between the dummy contact and the source;
wherein a distance between the dummy contact and the drain is less than a distance between the dummy contact and the source; and wherein a distance between the second dummy contact and the drain is less than a distance between the second dummy contact and the source; and/or
wherein a distance between one of the dummy contact and the second dummy contact and the drain is less than a distance between said one of the dummy contact and the second dummy contact and the source; and wherein a distance between the other of the dummy contact and the second dummy contact and the drain is greater than a distance between said other of the dummy contact and the second dummy contact and the source.

The integrate circuit may be incorporated into an electronic device.

A three-dimensional integrated circuit has been described herein. The three-dimension integrated circuit includes a first CMOS wafer and a second CMOS wafer disposed on and electrically connected to the first CMOS wafer. The second CMOS wafer comprises: a field effect transistor structure comprising a gate, a plurality of aligned pairs of sources and drains, the sources being disposed on one side of the gate and drains being disposed on an opposite side of the gate; an oxide layer disposed on the field effect transistor structure; a metal layer disposed on the oxide layer such that the oxide layer is between the metal layer and the field effect transistor structure; and a plurality of thermally conductive contacts disposed within the oxide layer. The thermally conductive contacts are each electrically isolated and in thermal contact with the field effect transistor structure. The three-dimension integrated circuit may include any of the following features or combinations thereof:
wherein the gate comprises a plurality of active areas defined as areas directly between the pairs of sources and drains and comprises a plurality of inactive areas defined between the active areas and, optionally, at terminal ends of the gate; and wherein the plurality of thermally conductive contacts are positioned above the gate;
wherein the plurality of thermally conductive contacts are positioned above inactive areas of the gate;
wherein one or more of the plurality of thermally conductive contacts are positioned above inactive areas of the gate and one or more of the plurality of thermally conductive contacts are positioned above active areas of the gate;
wherein the gate comprises a length defined between the pairs of sources and drains, the length extending from a source side of the gate to a drain side of the gate; and wherein one or more of the plurality of thermally conductive contacts are positioned closer to the drain side of the gate than the source side of the gate; and/or
wherein one or more of the plurality of thermally conductive contacts are positioned closer to the source side of the gate than the drain side of the gate.

A method of making a three-dimensional integrated circuit has been described herein. The method includes fabricating a first CMOS wafer; fabricating a second CMOS wafer; and
electrically connecting the first CMOS wafer and the second CMOS wafer. The second CMOS wafer comprises: a field effect transistor structure comprising a gate, a plurality of aligned pairs of sources and drains, the sources being disposed on one side of the gate and drains being disposed on an opposite side of the gate; an oxide layer disposed on the field effect transistor structure; a metal layer disposed on the oxide layer such that the oxide layer is between the metal layer and the field effect transistor structure; and a plurality of thermally conductive contacts disposed above the gate within the oxide layer. The thermally conductive contacts are each electrically isolated and in thermal contact with the field effect transistor structure. The method may include any of the following features or combinations thereof:
wherein the gate comprises a plurality of active areas defined as areas directly between the pairs of sources and drains and comprises a plurality of inactive areas defined between the active areas and, optionally, at terminal ends of the gate; and wherein one or more of the plurality of thermally conductive contacts are positioned above inactive areas of the gate; and/or
wherein one or more of the plurality of thermally conductive contacts are positioned above active areas of the gate.

Although various embodiments have been shown and described, the disclosure is not limited to such embodiments and will be understood to include all modifications and variations as would be apparent to one of ordinary skill in the art. Therefore, it should be understood that the disclosure is not intended to be limited to the particular forms disclosed; rather, the intention is to cover all modifications, equivalents, and alternatives falling within the spirit and scope of the disclosure as defined by the appended claims.

1. An integrated circuit, comprising:
a substrate;
a metal layer positioned above the substrate;
an oxide layer disposed between the substrate and the metal layer;
a transistor disposed on the substrate between the substrate and the oxide layer, the transistor comprising a source, a gate, and a drain; and
a dummy contact positioned within the oxide layer above and in thermal contact with the gate of transistor, wherein the dummy contact is electrically isolated and configured to convey heat generated by the transistor during operation of the integrated circuit to the metal layer.

2. The integrated circuit of claim 1, further comprising a thermally conductive via formed between the dummy contact and the metal layer.

3. The integrated circuit of claim 1, further comprising,
a second oxide layer disposed on the metal layer;
a second metal layer disposed on the second oxide layer; and
a thermally conductive via formed through the second oxide layer between the metal layer and the second metal layer, the thermally conductive via configured to convey the heat generated by the transistor to the second metal layer.

4. The integrated circuit of claim 1, which is a three dimensional integrate circuit comprising a plurality of stacked integrated circuits on a handle wafer, the handle wafer forming a bottom surface of the integrated circuit.

5. The integrated circuit of claim 4, wherein the transistor is disposed within a top integrated circuit of the plurality of stacked integrated circuits; and
wherein the top integrated circuit further comprises one or more stacked thermally conductive vias configured to convey the heat generated by the transistor to a top metal layer of the top integrated circuit.

6. The integrated circuit of claim 1, wherein the gate extends beyond the source and drain, and an active area of the gate is defined as an area of the gate directly between the source and the drain; and
wherein the dummy contact is positioned outside of the active area.

7. The integrated circuit of claim 6, further comprising a second dummy contact positioned within the oxide layer above the active area of the gate and in thermal contact with the gate, wherein the second dummy contact is electrically isolated and configured to convey heat generated by the transistor to the metal layer.

8. The integrated circuit of claim 6, wherein a distance between the dummy contact and the drain is less than a distance between the dummy contact and the source.

9. The integrated circuit of claim 7, wherein a distance between the dummy contact and the drain is less than a distance between the dummy contact and the source; and
wherein a distance between the second dummy contact and the drain is less than a distance between the second dummy contact and the source.

10. The integrated circuit of claim 7, wherein a distance between one of the dummy contact and the second dummy contact and the drain is less than a distance between said one of the dummy contact and the second dummy contact and the source; and
wherein a distance between the other of the dummy contact and the second dummy contact and the drain is greater than a distance between said other of the dummy contact and the second dummy contact and the source.

11. An electronic device comprising the integrated circuit of claim 1.

12. A three-dimensional integrated circuit, comprising:
a first CMOS wafer; and
a second CMOS wafer disposed on and electrically connected to the first CMOS wafer,
wherein the second CMOS wafer comprises:
a field effect transistor structure comprising a gate, a plurality of aligned pairs of sources and drains, the sources being disposed on one side of the gate and drains being disposed on an opposite side of the gate;
an oxide layer disposed on the field effect transistor structure;
a metal layer disposed on the oxide layer such that the oxide layer is between the metal layer and the field effect transistor structure; and
a plurality of thermally conductive contacts disposed within the oxide layer, the thermally conductive contacts each being electrically isolated and in thermal contact with the field effect transistor structure.

13. The three-dimensional integrated circuit of claim 12, wherein the gate comprises a plurality of active areas defined as areas directly between the pairs of sources and drains and comprises a plurality of inactive areas defined between the active areas and, optionally, at terminal ends of the gate; and
wherein the plurality of thermally conductive contacts are positioned above the gate.

14. The three-dimensional integrated circuit of claim 13, wherein the plurality of thermally conductive contacts are positioned above inactive areas of the gate.

15. The three-dimensional integrated circuit of claim 13, wherein one or more of the plurality of thermally conductive contacts are positioned above inactive areas of the gate and one or more of the plurality of thermally conductive contacts are positioned above active areas of the gate.

16. The three-dimensional integrated circuit of claim 13, wherein the gate comprises a length defined between the pairs of sources and drains, the length extending from a source side of the gate to a drain side of the gate; and
wherein one or more of the plurality of thermally conductive contacts are positioned closer to the drain side of the gate than the source side of the gate.

17. The three-dimensional integrated circuit of claim 13, wherein one or more of the plurality of thermally conductive contacts are positioned closer to the source side of the gate than the drain side of the gate.

18. A method of making a three-dimensional integrated circuit, comprising:
fabricating a first CMOS wafer;
fabricating a second CMOS wafer;
wherein the second CMOS wafer comprises:
a field effect transistor structure comprising a gate, a plurality of aligned pairs of sources and drains, the sources being disposed on one side of the gate and drains being disposed on an opposite side of the gate;
an oxide layer disposed on the field effect transistor structure;
a metal layer disposed on the oxide layer such that the oxide layer is between the metal layer and the field effect transistor structure; and
a plurality of thermally conductive contacts disposed above the gate within the oxide layer, the thermally conductive contacts each being electrically isolated and in thermal contact with the field effect transistor structure; and
electrically connecting the first CMOS wafer and the second CMOS wafer.

19. The method of claim 18, wherein the gate comprises a plurality of active areas defined as areas directly between the pairs of sources and drains and comprises a plurality of inactive areas defined between the active areas and, optionally, at terminal ends of the gate; and
wherein one or more of the plurality of thermally conductive contacts are positioned above inactive areas of the gate.

20. The method of claim 19, wherein one or more of the plurality of thermally conductive contacts are positioned above active areas of the gate.
